(19) United States
(12) Patent Application Publication
(10) Pub. No.: US 2015/0034368 A1
(43) Pub. Date: Feb. 5, 2015

(54) ELECTRODE ELEMENT USING SILVER NANO-WIRE AND MANUFACTURING METHOD THEREOF

(71) Applicant: KOREA ADVANCED INSTITUTE OF SCIENCE AND TECHNOLOGY, Daejeon (KR)

(72) Inventors: Min-Yang YANG, Daejeon (KR); Seung-a BACK, Daejeon (KR); Geon woo KIM, Daejeon (KR); Jaehak LEE, Daejeon (KR)

(73) Assignee: KOREA ADVANCED INSTITUTE OF SCIENCE AND TECHNOLOGY, Daejeon (KR)

(21) Appl. No.: 14/207,952

(22) Filed: Mar. 13, 2014

(30) Foreign Application Priority Data
Jul. 31, 2013 (KR) 1020130091221

(51) Int. Cl. H05K 1/02; B05D 1/38; H05K 1/09; B05D 3/06

(52) U.S. Cl. CPC H05K 1/0274; B05D 3/065; B05D 1/38; H05K 1/092; H05K 2201/032; H05K 2201/0776; H05K 2201/2054
USPC 174/253; 427/557; 427/558

(57) ABSTRACT

An electrode element using a silver nano-wire and a manufacturing method thereof are provided, according to which the electrode element has reinforced bonding of wire unit structures with low-temperature heat treatment and easily applicable as a polymer substrate, while improving haze phenomenon, deteriorating adhesion force of silver nano-wire layer, surface roughness and changing resistance over time. The manufacturing method of electrode element includes steps of forming a silver nano-wire layer on a substrate, coating an organo-metal (OM) compound solution on top of the silver nano-wire layer, reinforcing bonding of junctions formed between wire unit structures with a thermal energy locally generated at the junctions by surface Plasmon, by irradiating light onto the silver nano-wire layer with the OM compound coated thereon, and treating surface by applying sol-gel solution on the silver nano-wire layer treated by the Plasmon.

### CROSS-REFERENCES TO RELATED APPLICATION

This application claims priority from Korean Patent Application No. 10-2013-0091221, filed on Jul. 31, 2013, in the Korean Intellectual Property Office, the contents of which are incorporated herein by reference in its entirety.

### BACKGROUND

1. Field of the Invention

The present invention relates to an electrode element using silver nano-wire for application in semiconductor devices and displays, and a manufacturing method thereof.

2. Description of the Related Art

Most transparent electrodes currently used in the field of semiconductor devices and displays employ indium tin oxide (ITO).

ITO, which is solid solution of In₂O₃ and SnO₂, is known for high optical property in visible ray region and reflection property in infrared region, and also known as stable oxide at room temperature with relatively low electric resistance.

ITO is widely used in the transparent electrode such as solar battery, flat display panel, touch screen panel, LED and next-generation OLED, and also as the transparent electrodes for semiconductors.

However, cost for indium, which is the main ingredient of ITO, has risen rapidly around 2000 when demands for indium soared, to be almost 17 times higher. The annual average price for indium which was only US$87 per KG at that time increased to US$1489 in 2004, placing the transparent electrode product as one of the most expensive products.

Further, since ITO has strong brittleness, it easily breaks when exposed to external force. Accordingly, the material is hardly applicable for the next-generation display such as flexible display. Further, low transmittance and high sheet resistance hinders enlargement of the product.

Recently, efforts are actively made to develop transparent electrode material as a replacement for the ITO. Among the candidates, silver nano-wire is gaining increasing attention as the prominent candidate to replace ITO.

Silver nano-wire has good electric conductivity, while it has resistance around 80˜120Ω which is considerably lower than that of ITO (200˜400Ω). It is thus possible to achieve low resistance with relatively smaller amount than ITO, which is advantageous for the purpose of transparent electrode enlargement.

Additionally, since the silver nano-wire is formed as a slender, elongated nano-scale unit, it does not break even when the substrate bends. Accordingly, silver nano-wire is suitable for flexible display which seeks higher flexibility, and also has good pattern formation on surfaces.

However, the conductor using silver nano-wire has problem of haze phenomenon, since it is necessary to increase the amount of nano-wire to obtain low sheet resistance.

The ‘haze’ refers to degree of scattering of the light that passes transparent electrode. That is, a greater haze means a hazier state.

The transparent electrode using silver nano-wire has additional problems such as low contact force with the substrate and large surface roughness, and increasing resistance as time goes by, due to contact with air.

Technologies adopting silver nano-wire can be found in many reports including patent documents.

For example, Korean Patent No. 10-2008-0066658 discloses “Transparent conductor of nano-wire substrate” in which conductor layer including a silver nano-wire network buried in matrix is formed, with one side of the conductor layer being reinforced in its bonding by way of heating, and the other layer remaining un-heated, and the conductor layer with the reinforced bonding is produced under pressure.

However, the related technology such as KR Patent No. 10-2008-0066658 is hardly applicable for the purpose of polymer substrate of flexible display, since it is necessary to perform high-temperature heat treatment on the silver nano-wire to reduce resistance of the conductor.

### SUMMARY OF THE INVENTION

The present invention has been made to overcome the problems mentioned above, and accordingly, it is an object of the present invention to provide an electrode element using silver nano-wire which provides reinforced bonding of wire unit structures by way of low-temperature treatment which leads into low resistance, and which is applicable for polymer substrate and can improve shortcoming such as haze phenomenon, deteriorated bonding of silver nano-wire layers, surface roughness or varying resistance over time, and a manufacturing method thereof.

In order to achieve the above-mentioned objects, in one embodiment, a manufacturing method of an electrode element using a silver nano-wire is provided, which may include steps of forming a silver nano-wire layer on a substrate, coating an organo-metal (OM) compound solution on top of the silver nano-wire layer, reinforcing bonding of junctions formed between wire unit structures, with a thermal energy locally generated at the junctions by surface Plasmon, by irradiating light onto the silver nano-wire layer with the OM compound coated thereon, and treating surface by applying sol-gel solution on the silver nano-wire layer treated by the Plasmon.

In the step of coating an organo-metal (OM) compound solution on top of the silver nano-wire layer, the OM compound may be organic silver solution.

In the step of coating of OM compound solution on top of the silver nano-wire layer, the OM solution gravitates along the wire unit structures by capillary force and concentrated at the junctions and evaporated, leaving nano-particles contained in the organic silver solution concentrated at the junctions.

In the step of coating of OM compound solution on top of the silver nano-wire layer, the content of the silver with respect to the organic silver solution is 0.05 wt %.

The reinforcing bonding of junctions may include a step of irradiating the light onto the silver nano-wire layer through an UV lamp, after the organic metal compound is coated on the silver nano-wire layer.

In the step of reinforcing bonding of junctions, wavelength of the light irradiated through the UV lamp is so determined as to obtain light absorbance peak value of the substrate with the OM compound applied thereon.

The step of reinforcing bonding of junctions may include a step of irradiating the light onto the silver nano-wire layer through the UV lamp at a wavelength of 260 nm or 370 nm.

In the step of treating surface by applying sol-gel solution on the silver nano-wire layer, the sol-gel solution may be TiO₂.

In one embodiment, an electrode element using a silver nano-wire is provided, which may include a substrate, a silver nano-wire layer which comprises a plurality of wire unit structures and which is formed on the substrate, in which the silver nano-wire layer is formed in a manner in which organic silver solution is coated on a surface of the silver nano-wire layer and heated, thus leaving nano-particles contained in the organic silver solution concentrated at junctions formed between the wire unit structures, after which a light by a UV lamp is emitted onto the silver nano-wire layer with the organic silver solution coated thereon, thereby causing bonding of the junctions is reinforced by a thermal energy which is locally generated as a result of interaction with Plasmon generated at the junctions, and the surface of the silver nano-wire layer is treated by applying sol-gel solution thereon.

The content of the silver with respect to total weight of the organic silver solution may be 0.05 wt %, temperature of the heat applied to the silver nano-wire layer coated with the organic silver solution may be 90° C., and wavelength of the light emitted onto the silver nano-wire layer through the UV lamp may be either 260 nm or 370 nm.

According to an electrode element using silver nano-wire and a manufacturing method thereof according to various embodiments, nano-particles concentrate at junctions of the wire unit structures as a result of coating of organic silver solution on the silver nano-wire layer, and bonding of the junctions reinforces as a result of interaction with Plasmon. Accordingly, the electrode element using silver nano-wire according to various embodiment has reduced resistance of the silver nano-wire layer and reduced haze phenomenon.

Further, according to an electrode element using silver nano-wire and a manufacturing method thereof according to various embodiments, bonding of the nano unit structures is reinforced with heat which is generally locally on the silver nano-wire layer by Plasmon. Accordingly, since it is not necessary to involve hot-temperature heat, the electrode element is easily suitable for polymer substrate for use in flexible displays.

Further, according to an electrode element using silver nano-wire and a manufacturing method thereof according to various embodiments, bonding and surface roughness of the silver nano-wire layer are improved, while the resistance change is controlled because the silver nano-wire is prevented from being exposed to outside.

### BRIEF DESCRIPTION OF THE DRAWINGS

The foregoing and/or other aspects according to an embodiment will be more apparent upon reading the description of certain exemplary embodiments with reference to the accompanying drawings, in which:

FIG. 1 is a flowchart provided to explain a manufacturing method of an electrode element according to an embodiment;

FIG. 2 illustrates sequence of the electrode element manufacturing method of FIG. 1;

FIG. 3 is a perspective view of a nano unit structure being assembled in steps 2 and 3, according to an embodiment;

FIG. 4 is an image of junctions of silver nano-wire layers at step 3, according to an embodiment;

FIG. 5 is a graph representing relationships among content of organic silver solution coated on silver nano-wire layer, light absorbance according to light, and wavelength of the light, according to an embodiment;

FIG. 6 presents images for comparing wire unit structure bonding according to step 3, according to an embodiment;

FIG. 7 is a cross-section view of an electrode element manufactured according to an embodiment.

### DETAILED DESCRIPTION OF EXEMPLARY EMBODIMENTS

Hereinafter, exemplary embodiments of the present invention will now be described in detail with reference to the attached drawings. It should be noted that the same elements or components have the same reference numerals. While describing the present invention, a detailed description on well-known art or configurations will be omitted not to make the substance of the present invention equivocal.

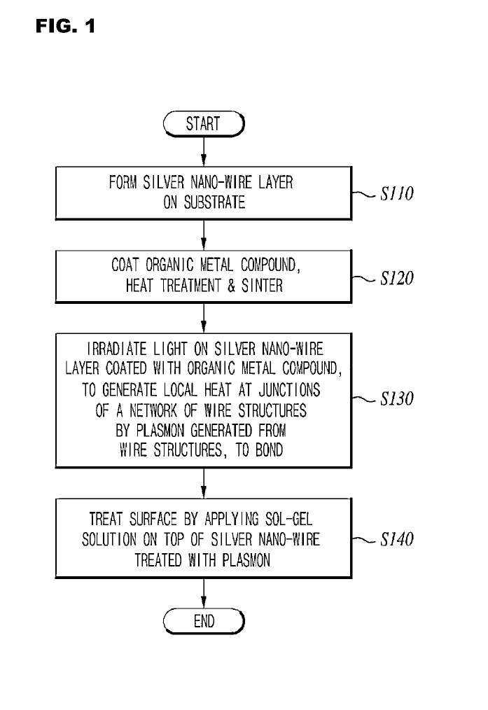

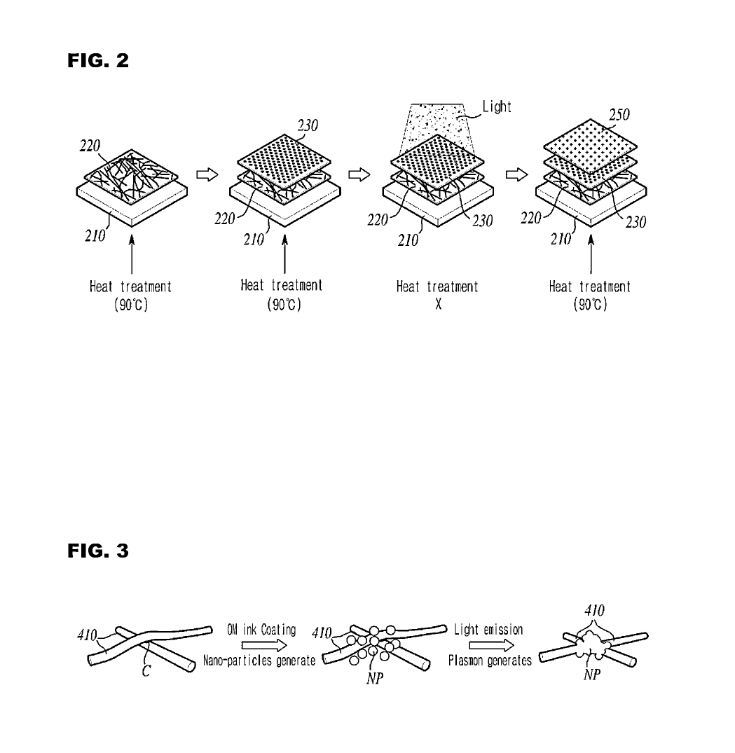

FIG. 1 is a flowchart provided to explain a manufacturing method of an electrode element according to an embodiment, and FIG. 2 illustrates sequence of operations carried out according to the electrode element manufacturing method of FIG. 1.

Referring to FIGS. 1 and 2, a manufacturing method of electrode element according to an embodiment includes a first step (S110) of forming silver nano-wire layer 220 on top of a substrate 210, a second step (S120) of coating organic metal compound 230 (i.e., organo-metal (OM) ink) on the silver nano-wire layer 220 formed at S110, a third step (S130) of bonding, by irradiating light onto the silver nano-wire layer 220 with the organic metal compound 230 coated thereon at S120, thus causing local heat to be generated at respective junctions (C, refer to FIG. 3) between wire unit structures 410 (refer to FIG. 3) of a network structure, by Plasmon effect generated from the wire unit structures 410, and a fourth step (S140) of treating surface by applying sol-gel solution on top of the silver nano-wire layer 220 treated with Plasmon.

Referring to FIG. 2, a manufacturing method of electrode element according to an embodiment will be explained in detail. First, the first step (S110) is performed to form silver nano-wire layer 220 on top of the substrate 210.

Hereinbelow, the transparent electrode for use in solar battery, semiconductor device or display will be explained with reference to certain embodiments. However, the transparent electrode will not be limited to certain embodiments provided herein, and may be used in a variety of applications such as conductors for semiconductor equipments, etc.

At S110, the substrate 210 may be glass substrate that is widely used in the field of solar batteries or displays, and in one embodiment, a polymer substrate suitable for next-generation flexible display may be implemented.

At least one of the transparent and conductor has high optical transmittance and high electric conductivity, and considering loss of voltage due to surface resistance when generated, low resistance is also necessary.

It is possible to apply the silver nano-wire layer 220 formed on top of the substrate 210 for use in devices of a variety of functions, by adjusting thickness thereof and flexibly adjusting transmittance and electric conductivity of the transparent electrode.

The silver nano-wire layer 220 may be formed on the substrate 120 by way of spin coating, bar coating or slot die coating.

For example, the silver nano-wire layer 220 which is approximately 50 nm in thickness has the sheet resistance of approximately 100˜150 [Ω/sq].

The thickness of the silver nano-wire layer 220 may be adjusted by increasing or decreasing the spin rate for spin coating process, or for bar coating, by increasing or decreasing transport speed of plate, or rotational velocity of the bar and diameter of the wire wound on the bar.

Further, it is possible to adjust transmittance and electric conductivity of the silver nano-wire according to the amount of silver nano-wire particles of the silver nano-wire layer 220.

Accordingly, by adjusting thickness and amount of particles of the silver nano-wire layer 220 depending on the types of the equipment where the transparent electrode is used, it is possible to meet the required performance.

For example, for the touch screen panel which needs to have higher transmittance than electric conductivity, transmittance can be increased, while for OLED which needs electric conductivity more importantly, the electric conductivity can be increased.

After the silver nano-wire layer is formed, the first step may preferably include heating to dry the same.

The temperature of the heating may preferably be 90° C. and within 100° C.

Referring to FIG. 2, the second step (S120) is performed to coat organic metal compound 230 on top of the silver nano-wire layer 220 formed at the first step (S110).

Accordingly, the contact resistance of the silver nano-wire layer 220 is reduced in the second step (S120), as the bonding of the wire unit structures 410, which form a network structure in the silver nano-wire layer 220, is reinforced by the coating of the organic metal compounds 230.

Further, the coating of the organic metal compound 230 can improve electric property, while maintaining the transmittance of the transparent electrode same, to thus reduce haze phenomenon.

The organic metal compound 230 may include organometallic ink containing therein silver nano-particles.

FIG. 3 illustrates resultant formation obtained as the nano-particles are converged at the junctions of the wire unit structures 410 in the second and third steps, according to an embodiment.

Referring to FIG. 3, when the organic metal compound 230 is coated on the silver nano-wire layer 220 in the second step (S120), the organic metal compound 230, which is in solution state, flows along the wire unit structures 410 forming the silver nano-wire layer 220.

After that, as the organic metal compound dries, the nano-particles (NP) contained in the organic metal compound selectively gravitate toward the junctions C of the wire unit structures 410 where the strong capillary force acts.

As a result, the NP converged at the junctions C of the wire unit structures 410 play a role of reinforcing the bonding force of the wire unit structures 410 and subsequently decreasing contact resistance.

After the coating of the organic metal compound on the silver nano-wire layer, the second step may preferably perform sintering by applying heat.

The temperature of the heat may preferably be 90° C. and within 100° C.

The third step (S130) is performed to reinforce bonding of the junctions C formed by the wire unit structures 410 by Plasmon reaction, by irradiating light onto the silver nano-wire layer 220 with the organic metal compound 230 coated thereon in the second step (S120).

Referring to FIG. 3, in the third step (S130), light is irradiated onto the silver nano-wire layer 220 to generate surface Plasmon on the wire unit structures 410 which form a network structure in the silver nano-wire layer 220, and stronger bonding is achieved due to the action of the surface Plasmon in a state that the nano-particles are converged at the junctions C of the network.

As a result, the contact resistance at the junctions C of the wire unit structures 410 is reduced by the action explained above, and the transparent electrode in the final form can have further reduced haze phenomenon.

Accordingly, the third step (S130) according to an embodiment reinforces the bonding of the wire unit structures 410 by applying the light onto the silver nano-wire layer 220.

In one embodiment, the polymer substrate, which is generally easily breakable in process, can be applied, since the heating is performed at a temperature around 90° C.

Meanwhile, the light may be emitted from a UV lamp in the third step, according to an embodiment.

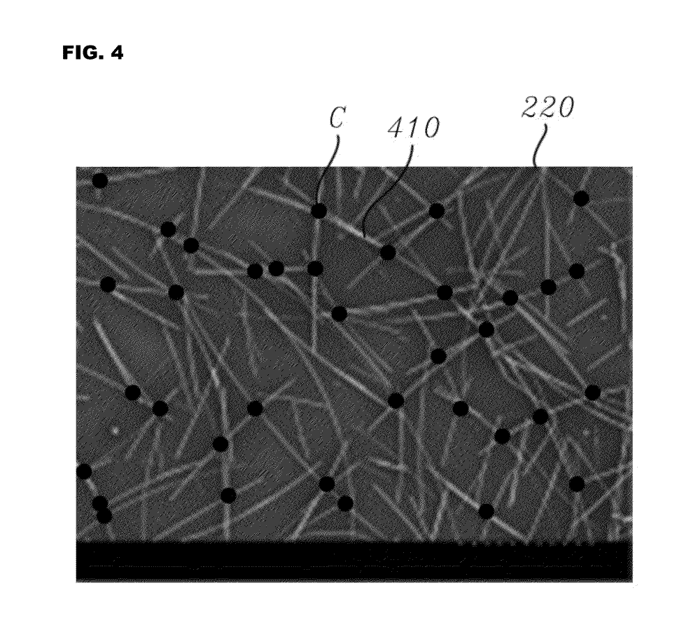

FIG. 4 shows the junctions of the silver nano-wire layer 220 reacting to the light emitted in the third step (S130).

Referring to FIG. 4, the silver nano-wire layer 220 includes a network of a plurality of wire unit structures 410 in nano-scale size.

In response to light emitted onto the silver nano-wire layer 220, the surface Plasmon generated from the wire unit structures 410 interact at the respective junctions C, and thus generates thermal energy.

Since the thermal energy is generated within the silver nano-wire layer 220 in a local form, high-temperature heating is not necessary, when considering the entire area of the silver nano-wire layer 220.

In one embodiment, the nano-particles are converged at the respective junctions C formed by the wire unit structures 410 by the coating of the organic metal compound 230, and bonding is reinforced by the action of the surface Plasmon.

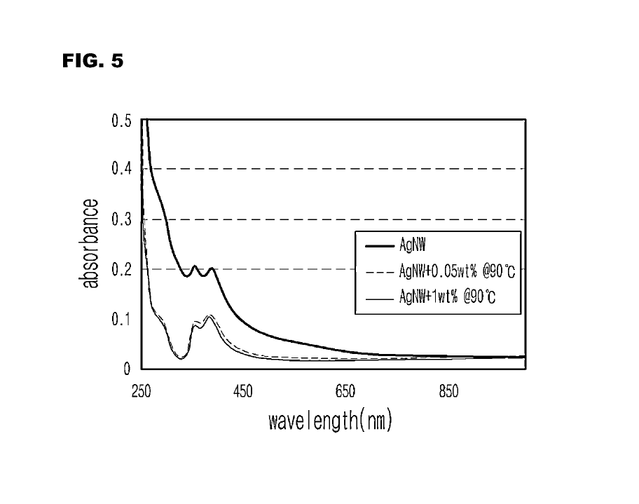

FIG. 5 is a graph representing result of evaluation on light emitted through the UV lamp and temperature for heating, according to an embodiment, which shows the relationships among content of organic silver solution with respect to the silver nano-wire layer 220, temperature of heat applied to the silver nano-wire layer 220, and wavelength of the light and absorbance.

Meanwhile, the content of the organic silver solution for coating on the silver nano-wire layer is preferably 0.05 wt. %, which is, as a result of several experiments, confirmed to be the value that can achieve maximum sheet resistance improvement without compromising transmittance.

Accordingly, with the concentration fixed at 0.05 wt %, change of the absorbance peak as measured was almost negligible, since the amount of nano-particles (0.05 wt %) is too small to influence the absorbance peak, while the comparative example with 1 wt % of coating showed overall increased absorbance as illustrated in FIG. 5.

According to an embodiment, in the second step, the content of the silver coated on the silver nano-wire layer 220 is preferably 0.05 wt. % with respect to the weight of the organic silver solution, and after the coating of the organic silver solution, the light may preferably be emitted through the UV lamp at one of the wavelengths of 260 nm, and 370 nm.

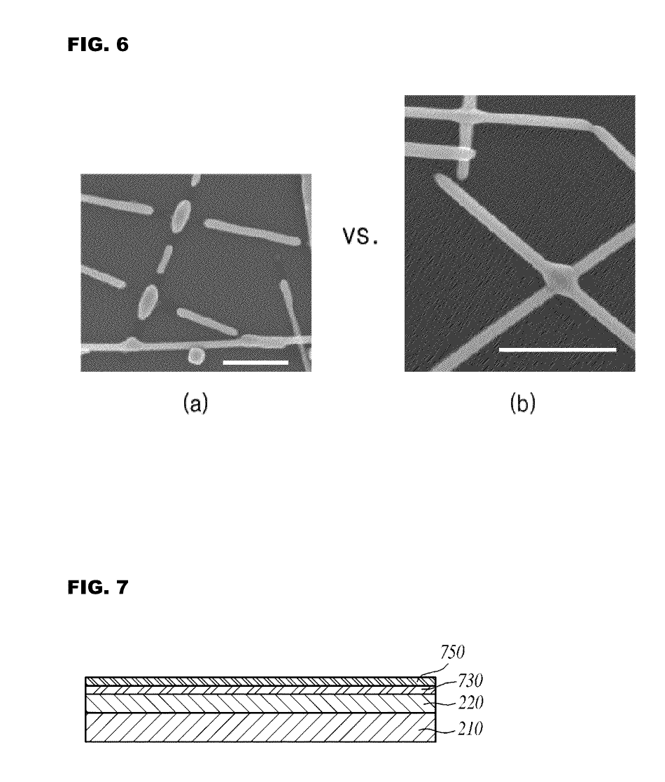

FIG. 6 shows bonding of the respective wire unit structures 410 by way of heating with hot plate or convection oven, compared to reinforced bonding according to an embodiment.

Referring to FIG. 6, the conventional method of using hot plate or convection oven accompanies heating of the silver nano-wire layer 220 at high temperature which generally exceeds 150° C., according to which the wire unit structures 410 are severed by the excessive heat.

As explained above, the need for high temperature heating hinders application in substrate 210 which is weak to heat, and it is thus difficult to apply the silver nano-wire for the polymer substrate to be used in the flexible display transparent electrode.

In an embodiment, the above-mentioned shortcoming is overcome. That is, according to an embodiment, the wire unit structures 410 are bonded by the locally-generated heat in the low-temperature process, and therefore, since the bonding at the junctions C of the wire unit structures 410 is accomplished with the locally-generated heat, it is no longer necessary to add high temperature heat. As a result, stable structure is obtained, and the structure is applicable even for the polymer substrate of the flexible display which is generally very weak to high temperature.

Referring back to FIG. 2, the fourth step (S140) is performed to treat the surface by applying the sol-gel solution 250 on top of the silver nano-wire layer 220 which is treated with Plasmon.

In one embodiment, the sol-gel solution may be TiO₂.

The silver nano-wire layer is subject to oxidation especially when it is kept exposed to external air for a predetermined period of time, which leads into changing resistance.

By applying sol-gel solution 250 such as titanium dioxide (TiO₂), the silver nano-wire layer 220 is prevented from exposure to external air and maintained in safe environment. Accordingly, change in resistance is kept minimized.

After the sol-gel solution is applied on the silver nano-wire layer in the fourth step, it is preferable to apply heat for drying purpose.

The temperature of the heat may preferably be 90° C. and within 100° C.

Accordingly, by applying sol-gel solution 250 such as TIO₂ into pores formed in the surface of the transparent electrode, surface roughness improves, bonding of the silver nano-wire layer 220 improves, and bonding of the junctions C of the wire unit structures 410 is further reinforced as a result of condensation by TiO₂ sol-gel transition. As a result, the contact resistance of the transparent electrode is further reduced.

According to a manufacturing method including the first to fourth steps (S110 to S140), electrode element can be produced with low temperature heating treatment, providing sufficiently low resistance property that is comparable to the resistance property improvement obtained by high temperature heating treatment, by utilizing locally generated heats on the silver nano-wire layer 220 by Plasmon and bonding reinforcement with sol-gel solution 250, which is accordingly suitable for the production of polymer substrate for use in flexible display with low temperature heating treatment.

Hereinbelow, the electrode element using silver nano-wire according to another embodiment will be explained.

The electrode element using the silver nano-wire explained below may be that which is produced according to the manufacturing method including first to fourth steps (S110 to S140) according to the embodiment explained above.

The like elements will be given the same reference numerals as those used in the embodiment explained above, and will be briefly explained, when necessary, for the sake of brevity.

FIG. 7 is a cross section view of an electrode element using a silver nano-wire according to an embodiment.

Referring to FIG. 7, the electrode element according to an embodiment includes a substrate 210, a silver nano-wire layer 220, an organic silver solution-coated layer 730, and TiO₂ coated layer 750.

The silver nano-wire layer 220 is formed, with a plurality of nano-sized wire unit structures 410 (see FIGS. 3 and 4) formed therein.

To be specific, when the organic silver solution-coated layer 730 is formed on the surface of the silver nano-wire layer 220, the nano-particles contained in the organic silver solution are concentrated at the junctions C (see FIGS. 3 and 4) of the wire unit structures 410, so that the junctions C have reinforced bonding by the thermal energy which is locally generated by the interaction of Plasmon generated at the junctions C of the wire unit structures 410, when the light of the UV lamp and heat are simultaneously applied on the silver nano-wire layer 220.

The surface is treated by forming TiO₂ coating layer 750 on the surface of the silver nano-wire layer 220.

As explained above, the electrode element using silver nano-wire and the manufacturing method according to various embodiment reduce haze phenomenon, by the structure of concentrated distribution of nano-particles by way of organic silver solution coating, and reinforced bonding of the junctions C by Plasmon, and can be manufactured with low temperature heat treatment by utilizing Plasmon effect and thus is applicable as the polymer substrate for use in flexible display.

Further, since the surface of the silver nano-wire layer 220 with reinforced bonding is coated with sol-gel solution 250, surface roughness improves and changes in resistance due to oxidation of silver nano-wire for exposure to air, can be controlled.

The foregoing exemplary embodiments and advantages are merely exemplary and are not to be construed as limiting the present invention. The present teaching can be readily applied to other types of apparatuses. Also, the description of the exemplary embodiments of the present inventive concept is intended to be illustrative, and not to limit the scope of the claims.

What is claimed is:

1. A manufacturing method of an electrode element using a silver nano-wire, the manufacturing method comprising steps of:
forming a silver nano-wire layer on a substrate;
coating an organo-metal (OM) compound solution on top of the silver nano-wire layer;
reinforcing bonding of junctions formed between wire unit structures with a thermal energy locally generated at the junctions by surface Plasmon, by irradiating light onto the silver nano-wire layer with the OM compound coated thereon; and
treating surface by applying sol-gel solution on the silver nano-wire layer treated by the Plasmon.

2. The manufacturing method of claim 1, wherein the step of forming silver nano-wire layer on the substrate comprises a step of applying heat after forming the silver nano-wire layer on the substrate.

3. The manufacturing method of claim 1, wherein during the step of coating of OM compound solution on top of the silver nano-wire layer, the OM solution gravitates along the wire unit structures by capillary force and concentrated at the junctions and evaporated, leaving nano-particles contained in the organic silver solution concentrated at the junctions.

4. The manufacturing method of claim 1, wherein the step of coating of OM compound solution on top of the silver nano-wire layer comprises a step of applying heat after coating the OM compound on top of the silver nano-wire layer.

5. The manufacturing method of claim 1, wherein in the step of coating an organo-metal (OM) compound solution on top of the silver nano-wire layer, the OM compound is organic silver solution.

6. The manufacturing method of claim 5, wherein in the step of coating of OM compound solution on top of the silver nano-wire layer, the content of the organic silver solution with respect to total weight of the silver nano-wire layer and the organic silver solution is 0.05 wt %.

7. The manufacturing method of claim 1, wherein, the step of reinforcing bonding of junctions comprises irradiating the light onto the silver nano-wire layer through an UV lamp.

8. The manufacturing method of claim 7, wherein, in the step of reinforcing bonding of junctions, wavelength of the light irradiated through the UV lamp is so determined as to obtain light absorbance peak value of the substrate with the OM compound applied thereon.

9. The manufacturing method of claim 7, wherein the step of reinforcing bonding of junctions comprises a step of irradiating the light onto the silver nano-wire layer through the UV lamp at a wavelength of 260 nm or 370 nm.

10. The manufacturing method of claim 1, wherein, in the step of treating surface by applying sol-gel solution on the silver nano-wire layer, the sol-gel solution is TiO₂.

11. The manufacturing method of claim 1, wherein the step of treating surface by applying sol-gel solution on the silver nano-wire layer comprises applying heat after applying the sol-gel solution on the silver nano-wire layer.

12. The manufacturing method of claim 2, wherein temperature of the heat applied to the silver nano-wire layer is 90° C. or higher, and lower than 100° C.

13. An electrode element using a silver nano-wire, comprising:
a substrate;
a silver nano-wire layer which comprises a plurality of wire unit structures and which is formed on the substrate, wherein
the silver nano-wire layer is formed in a manner in which organic silver solution is coated on a surface of the silver nano-wire layer and heated, thus leaving nano-particles contained in the organic silver solution concentrated at junctions formed between the wire unit structures, after which a light by a UV lamp is emitted onto the silver nano-wire layer with the organic silver solution coated thereon, thereby causing bonding of the junctions is reinforced by a thermal energy which is locally generated as a result of interaction with Plasmon generated at the junctions, and
the surface of the silver nano-wire layer is treated by applying sol-gel solution thereon.

14. The electrode element of claim 13, wherein the content of the silver with respect to the organic silver solution is 0.05 wt %,
temperature of the heat applied to the silver nano-wire layer coated with the organic silver solution is 90° C., and
wavelength of the light emitted onto the silver nano-wire layer through the UV lamp is either 260 nm or 370 nm.

15. The manufacturing method of claim 4, wherein temperature of the heat applied to the silver nano-wire layer is 90° C. or higher, and lower than 100° C.

16. The manufacturing method of claim 11, wherein temperature of the heat applied to the silver nano-wire layer is 90° C. or higher, and lower than 100° C.
